(19) United States
(12) Patent Application Publication
(10) Pub. No.: US 2023/0002896 A1
(43) Pub. Date: Jan. 5, 2023

(54) REACTION CHAMBER

(71) Applicant: BEIJING NAURA MICROELECTRONICS EQUIPMENT CO., LTD., Beinjing (CN)

(72) Inventors: Zhongkai HE, Beijing (CN); Yandong RONG, Beijing (CN)

(21) Appl. No.: 17/941,923

(22) Filed: Sep. 9, 2022

Related U.S. Application Data
(63) Continuation of application No. PCT/CN2021/076804, filed on Feb. 19, 2021.

(30) Foreign Application Priority Data
Mar. 10, 2020 (CN) 202010161690.4

(51) Int. Cl. C23C 16/458; C23C 16/455; H01L 21/768; C23C 16/44

(52) U.S. Cl. CPC C23C 16/4585; C23C 16/45591; H01L 21/76897; C23C 16/4408; H01L 21/76877

(57) ABSTRACT

A reaction chamber includes a chamber body and a base. The base is arranged in the chamber body. The base includes a carrier member, a first block ring, and a second block ring. The carrier member is configured to carry a substrate and an edge member arranged around the carrier member. A height of an upper surface of the carrier member is greater than a height of an upper surface of the edge member. The first block ring is arranged on the upper surface of the edge member and around the carrier member. The upper surface of the carrier member is higher than an upper surface of the first block ring. The second block ring is on the upper surface of the first block ring. The second block ring includes a body member and a shield member.

### CROSS-REFERENCE TO RELATED APPLICATION

This application is a continuation of International Application No. PCT/CN2021/076804, filed on Feb. 19, 2021, which claims priority to Chinese Patent Application No. 202010161690.4, filed on Mar. 10, 2020, the entire contents of all of which are incorporated herein by reference.

### TECHNICAL FIELD

The present disclosure generally relates to the semiconductor manufacturing technical field and, more particularly, to a reaction chamber.

### BACKGROUND

A tungsten plug (W-plug) is a process that is widely used in the semiconductor industry, in which metal tungsten is filled in a via or trench. With good conductivity and anti-electromigration characteristics of the metal tungsten, a process requirement of electrical conduction between a front device and a rear device is realized.

In current industrial systems, a chemical vapor deposition (CVD) method is used to perform tungsten deposition. At present, to prevent the tungsten from being deposited on an edge of a substrate during the process, that is, an edge exclusion region is left at the edge of the substrate, an edge purge gas flow needs to be added at the edge of the substrate.

However, since a flow rate of the process gas is relatively fast, stay time of the process gas at the substrate is relatively short, a thickness of a film formed at the edge of the substrate is relatively narrow, and uniformity of the over film thickness on the substrate is poor.

### SUMMARY

Embodiments of the present disclosure provide a reaction chamber, including a chamber body and a base. The base is arranged in the chamber body. The base includes a carrier member, a first block ring, and a second block ring. The carrier member is configured to carry a substrate and an edge member arranged around the carrier member. A height of an upper surface of the carrier member is greater than a height of an upper surface of the edge member. The first block ring is arranged on the upper surface of the edge member and around the carrier member. The upper surface of the carrier member is higher than an upper surface of the first block ring. The second block ring is on the upper surface of the first block ring. The second block ring includes a body member and a shield member. The shield member is arranged on a side of the body member away from the first block ring. The shield member protrudes from a surface of the second block ring opposite to the carrier member. The shield member is configured to shield an edge of the upper surface of the substrate.

Another aspect of the present disclosure provide a semiconductor device including the reaction chamber described above.

With the carrier device provided by embodiments of the present disclosure, since the upper carrier member is higher than the upper surface of the first block ring, the lower surface of the second block ring is lower than the upper surface of the carrier member. Compared to the existing technology, the height of the second block ring may be lowered as a whole in embodiments of the present disclosure, and the dimension of the exhaust gas channel between the second block ring and the top of the reaction chamber may be increased. Thus, the flow rate of the process gas that flows by the edge of the substrate may be reduced to cause the flow rate of the process gas of the edge region above the surface of the substrate to be consistent with the flow rate of the process gas of another region. Therefore, the uniformity of the overall film thickness of the substrate may be increased.

### BRIEF DESCRIPTION OF THE DRAWINGS

The accompanying drawings described herein are used to provide a further understanding of the present disclosure, constitute a part of the present disclosure, and explain the present disclosure with specific embodiments below. However, the accompanying drawings do not form a limitation to the present disclosure.

FIG. 1 is a schematic diagram showing a blowing gas flow at an edge of a substrate in a chemical vapor deposition process.

FIG. 2 is a schematic curve diagram showing a thickness of a thin-film on the substrate.

FIG. 3 is a schematic diagram showing a part of the reaction chamber according to embodiments of the present disclosure.

FIG. 4 is a schematic diagram of a first block ring and a second block ring according to the first embodiment of the present disclosure.

FIG. 5 is a schematic diagram showing a comparison between a block ring structure according to some embodiments of the present disclosure.

FIG. 6 is a schematic diagram of a reaction chamber according to some embodiments of the present disclosure.

### DETAILED DESCRIPTION OF THE EMBODIMENTS

Specific embodiments of the present disclosure are described in detail below in connection with the accompanying drawings. Embodiments described here are only used to illustrate and explain the present disclosure, and are not intended to limit the present disclosure.

In many semiconductor devices, metal tungsten deposition is mainly deposited by a chemical vapor deposition (CVD) method. With the CVD method, metal filling of a via and a trench can substantially be realized. A critical dimension (CD) of an early semiconductor device is relatively large, and a depth-to-width ratio of the hole or trench is also relatively small. Thus, filling such a structure is not a very serious challenge for a CVD process. With advancements in the semiconductor technology, the CD of the semiconductor device tends to be miniaturized. For a tungsten plug process, the via and trench with a small opening and a large depth-to-width ratio gradually become a difficulty in the process. The metal tungsten filled in the via and trench is required that no pore or hole is left if possible, the impurities are as few as possible, and the resistivity is relatively low.

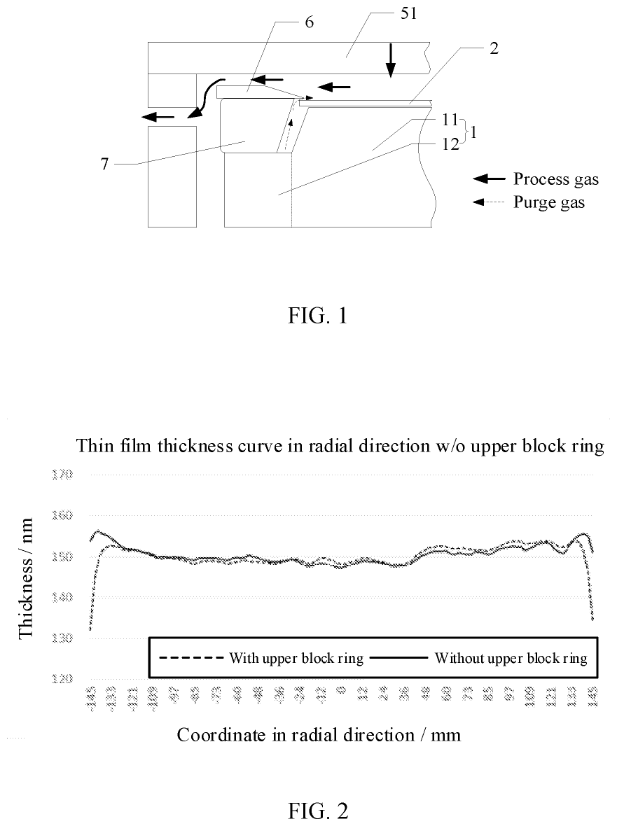

To prevent the tungsten from being deposited on an edge of a substrate during the process, that is, an edge exclusion region is left at the edge of the substrate, an edge purge gas flow needs to be added at the edge of the substrate. FIG. 1 is a schematic diagram showing the edge purge gas flow at the edge of the substrate in the chemical vapor deposition process in the existing technology. As shown in FIG. 1, when the process is performed, an upper block ring 6 and a lower block ring 7 are arranged at an edge of a base 1. An inner edge part of the upper block ring 6 has a certain shielding on an edge of a substrate 2, and a gap is reserved between the upper block ring 6 and the substrate 2 in a vertical direction. Thus, a purge gas channel is formed among the upper block ring 6, the lower block ring 7, the base 1, and the substrate 2. When the edge purge gas flow is blown out from the gas channel (as indicated by a dotted arrow in FIG. 1), a reactant distributed on a region of a surface of the substrate 2, which is shielded by the upper block ring 6, is blown away. Thus, a thin film cannot be deposited in the region. Therefore, forming a desired edge removal region is formed at the edge of the surface of the substrate 2. The remaining gas after the reaction enters an exhaust gas port through an exhaust gas channel between the upper surface of the upper block ring 6 and the top of the reaction chamber to be discharged out from the reaction chamber.

However, to place the upper block ring 6 above the surface of the substrate 2 to perform shielding, an upper surface of the lower block ring 7 is generally positioned higher than the upper surface of the substrate 2. As shown in FIG. 1, a distance between the upper block ring 6 and the chamber upper cover 51 of the reaction chamber is relatively small and is generally 10% to 50% narrower than a distance between the substrate 2 and the chamber upper cover 51 of the reaction chamber. Thus, the exhaust gas channel between the upper surface of the upper block ring 6 and a chamber upper cover 51 of the reaction chamber is relatively narrow. Since a flow rate of the process gas flowing through the exhaust gas channel is relatively fast, stay time of the process gas at the substrate 2 is relatively short, a thickness of a film formed at the edge of the substrate 2 is relatively narrow, and uniformity of the over film thickness on the substrate 2 is poor.

FIG. 2 is a schematic curve diagram showing a thickness of a thin film on the substrate in the existing technology. As shown in FIG. 2, when the upper block ring 6 is provided, a dashed line represents a thickness distribution curve of a thin film deposited on different regions of the substrate 2. When the upper block ring 6 is not provided, a solid line represents a thickness distribution curve of a thin film deposited on different regions of the substrate 2. In FIG. 2, when the upper block ring 6 is not provided, the thickness distribution curve of the thin film is relatively flat, that is, the thickness of the thin film on the entire surface of the substrate 2 is relatively uniform. When the upper block ring 6 is provided, the thickness of the thin film shows a tendency of a sharp decrease in a region greater than a radius of 135 mm on the substrate 2. That is, the thickness uniformity of the thin film on the entire surface of the substrate 2 is poor.

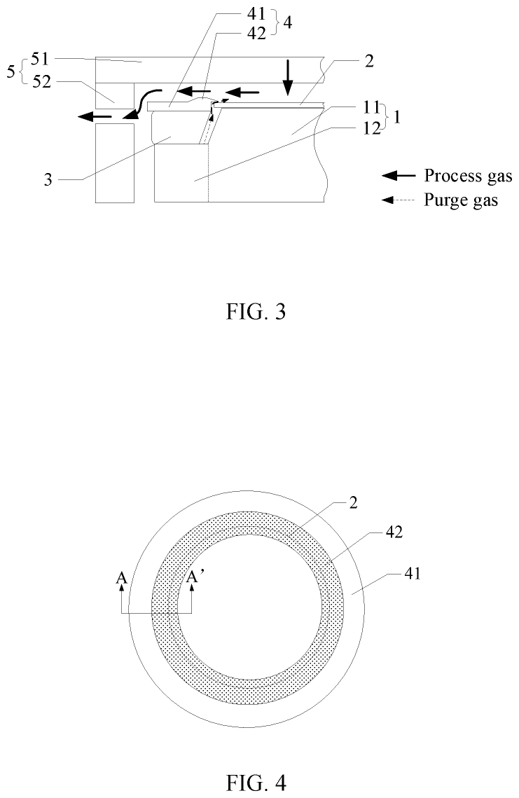

In order to solve the above problem, embodiments of the present disclosure provide a reaction chamber. FIG. 3 is a schematic diagram showing a part of the reaction chamber according to embodiments of the present disclosure. FIG. 4 is a top view of a second block ring according to embodiments of the present disclosure. As shown in FIG. 3 and FIG. 4, the reaction chamber includes a chamber body 5 and a base 1 arranged in the chamber body 5. The base 1 includes a carrier member 11 for carrying the substrate 2 and an edge member 12 arranged around the carrier member 11. A height of an upper surface of the carrier member 11 is greater than a height of an upper surface of the edge member 12.

The reaction chamber further includes a first block ring 3 and a second block ring 4. The first block ring 3 is arranged on the upper surface of the edge member 12. The first block ring 3 is arranged around the carrier member 11. The upper surface of the carrier member 11 is higher than the upper surface of the first block ring 3. The second block ring 4 is arranged on the upper surface of the first block ring 3 (i.e., a side facing away from the edge member 12). The second block ring 4 includes a body member 41 and a shield member 42 arranged on a side of the body member 41 away from the first block ring 3. The shield member 42 protrudes from a surface of the second block ring 4 opposite to the carrier member 11. The shield member 42 is configured to shield an edge of the upper surface of the substrate 2. As shown in FIG. 4, a dotted line is an edge contour line of the substrate 2, and a region between the edge contour line and an inner peripheral edge line of the shield member 42 is a region where the substrate 2 is shielded by the shield member 42.

Since the upper surface of the carrier member 11 is higher than the upper surface of the first block ring 3, a lower surface of the second block ring 4 is also lower than a lower surface of the carrier member 11. Compared with a solution of the entire lower surface of the upper block ring 6 of FIG. 1 being higher than the upper surface of the carrier member 11, the overall height of the second block ring 4 is reduced in the embodiments of the present disclosure. Thus, a dimension of the gas channel between the second block ring 4 and the top of the reaction chamber may be increased to further reduce the flow rate of the process gas flowing through the edge of the substrate. Therefore, the flow rate of the process gas in the edge region above the surface of the substrate may be consistent with the flow rates of the process gas in other regions, thereby improving the overall film thickness uniformity of the substrate.

In the embodiment, the shield member 42 may be arranged on a side of the body member 41 close to the carrier member 11, and a thickness of the shield member 42 may be set as small as possible. Thus, the overall thickness of the second block ring 4 may be reduced as much as possible.

As shown in FIG. 3, a purge gas channel is formed between an inner peripheral surface of the first block ring 3, an inner peripheral surface of the body member 41 of the second block ring 4, an upper surface of the edge member 12, an outer peripheral surface of the carrier member 11, a bottom surface of a protrusion of the shield member 42, and an outer peripheral surface and the edge of the upper surface of the substrate 2. The purge gas may be outputted to the edge of the upper surface of the substrate 2 after passing through the purge gas channel to blow the process gas at the edge away and prevent the process gas from depositing at the edge. Thus, an edge exclusion region may be formed at the edge of the upper surface of the substrate 2. A channel that is configured to transfer the purge gas may be arranged in the edge member 12. A gas outlet of the channel may be located on the upper surface of the edge member 12, and between the inner peripheral surface of the first block ring 3 and the outer peripheral surface of the carrier member 11 and may be configured to transfer the purge gas into the purge gas channel.

In some embodiments, the base 1 may be connected to the drive mechanism. The drive mechanism may be configured to drive the base 1 to ascend and descend and/or rotate. The second block ring 4 may be fixed in a predetermined position in the reaction chamber. When the base 1 is descended, the first block ring 3 may descend with the base 1, and the second block ring 4 may remain in the original position. At this time, the first block ring 3 and the second block ring 4 may be separated from each other. Thus, the substrate 2 may be placed on the upper surface of the base 1 without being blocked by the second block ring 4. When the base 1 is ascended to a process position, the first block ring 3 may ascend with the base 1 until the base 1 is in contact with the second block ring 4. At this time, the shield member 42 of the second block ring 4 may shield the edge of the upper surface of the substrate 2 to perform the deposition process.

In some embodiments, a first predetermined vertical distance is provided between the lower surface of the shield member 42 and the upper surface of the carrier member 11. The lower surface of the shield member 42 may be a surface of the shield member 42 facing the body member 41. The upper surface of the carrier member 11 may be a carrier surface that is configured to carry the substrate 2. The first predetermined vertical distance may be greater than the thickness of the substrate 2 that is to be carried. Thus, when the base 1 is in the process position, and the second block ring 4 is in contact with the first block ring 3, a gap may be reserved between the lower surface of the protrusion of the shield member 42 and the upper surface of the substrate 2 to facilitate the purge gas to flow out from the gap.

In some embodiments, a second predetermined vertical distance may be provided between the upper surface of the body member 41 and the upper surface of the carrier member 11, and the second predetermined vertical distance may be less than or equal to the first predetermined vertical distance. The upper surface of the body member 41 may be a surface away from the surface of the first block ring 3. Since the second predetermined vertical distance is less than or equal to the first predetermined vertical distance, the upper surface of the body member 41 may be not higher than the lower surface of the shield member 42. Thus, a width of the gas channel formed between the upper surface of the body member 41 and the chamber upper cover 51 may be increased to further reduce the flow rate of the process gas.

In some embodiments, the body member 41 of the second block ring 4 and the shield member 42 may be an integral structure to facilitate manufacturing and formation of the purge gas channel.

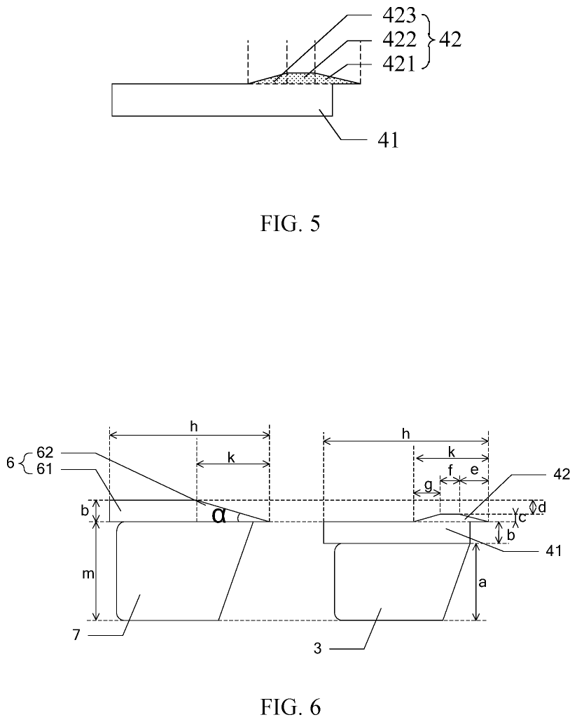

FIG. 5 is a schematic cross-sectional diagram along line A-A′ of FIG. 4. As shown in FIG. 3 to FIG. 5, the shield member 42 includes an outer ring member 423, a flat member 422, and an inner ring member 421 arranged in a direction close to the carrier member 11 in sequence. Along a direction close to the carrier member 11, the thickness of the inner ring member 421 gradually decreases, and the thickness of the outer ring member 423 gradually increases. Optionally, along the direction close to the carrier member 11, the thickness of the flat member 422 is approximately the same, that is, the upper surface of the flat member 422 is substantially flat. By gradually changing the thicknesses of the inner ring member 421 and the outer ring member 423 of the shield member 42, the resistance of the shield member 42 to the process gas may be reduced when the process gas flows by above the shield member 42.

In some embodiments, a cross-section of the entire shield member 42 is trapezoidal in a radial direction of the shield member 42. Further, as shown in FIG. 5, the inner ring member 421, the outer ring member 423, and the flat member 422 have the same size in the radial direction of the shield member 42. Thus, a longitudinal cross-section of the whole shield member 42 may form an isosceles trapezoid in the radial direction of the shield member 42.

In some embodiments, FIG. 6 is a comparison diagram of the block ring structure provided by embodiments of the present disclosure and the block ring structure in the existing technology. A left picture of FIG. 6 illustrates the upper block ring 6 and the lower block ring 7. The right picture of FIG. 6 illustrates the first block ring 3 and the second block ring 4 provided by embodiments of the present disclosure. As shown in FIG. 1 and the left picture of FIG. 6, the upper block ring 6 in the existing technology includes a first portion 61 arranged on an outer side and a second portion 62 arranged on an inner side. A thickness of the first portion 61 is approximately the same along the direction close to the carrier member 11. A thickness of the second portion 62 gradually decreases along the direction close to the carrier member 11. An angle between an inclined surface and a lower surface of the second member 62 is α. A distance between the lower surface of the upper block ring 6 and the upper surface of the edge member 12 is m. The thickness of the first member 61 of the upper block ring 6 is b. A radial width of the lower block ring 7 is h. A radial width of the second member 62 is k. In summary, a distance between the upper surface of the upper block ring 6 and the upper surface of the edge member 12 is b+m.

As shown in FIG. 3 and the right picture of FIG. 6, a longitudinal cross-section of the shield member 42 of embodiments of the present disclosure is an isosceles trapezoid in the radial direction of the shield member 42. Two bottom angles of the isosceles trapezoid are both α. A distance between the lower surface of the shield member 42 and the upper surface of the edge member 12 is m. The thickness of the first block ring 3 is a. The thickness of the body member 41 is b, where m−a=b. The thickness of the shield member 42 is c, where b−c=d. A radial width of the second block ring 4 is h. A radial width of the shield member 42 is k. A radial width e of the inner ring member 421, a radial width f of the flat member 422, and a radial width g of the outer ring member 423 are the same and equal to ⅓ k. In summary, a distance between the upper surface of the second block ring 4 and the upper surface of the edge member 12 is a+b+c=m+c in embodiments of the present disclosure.

In the existing technology, the distance between the upper surface of the upper block ring 6 and the upper surface of the edge member 12 is x=b+m. In embodiments of the present disclosure, the distance between the upper surface of the second block ring 4 and the upper surface of the edge member 12 is y=m+c, and x−y=b−c=d. A distance between a highest point of the second block ring 4 and the upper surface of the edge member 12 in embodiments of the present disclosure is less than a distance between a highest point of the upper block ring 6 and the upper surface of the edge member 12 in the existing technology, and a difference between the two distances is d.

In embodiments of the present disclosure, the radial width e of the inner ring member 421, the radial width f of the flat member 422, and the radial width g of the outer ring member 423 may be set between 1 mm and 3 mm. The thickness of the body member 41 of the second block ring 4 may be set between 2 mm and 8 mm, and preferably, may be set between 3 mm and 4 mm. The thickness of the shield member 42 may be set between 0.7 mm and 2.7 mm. The distance between the upper surface of the shield member 42 and the upper surface of the substrate 2 may be set to be less than 2 mm, and preferably, may be set to be less than 1 mm. By adjusting a magnitude of d (e.g., making d=⅓b), a dimension of the exhaust gas channel between the second block ring 4 and the chamber upper cover 51 of the reaction chamber may be increased by 10% -50% compared to the existing technology. The distance between the second block ring 4 and the chamber upper cover 51 is similar to the distance between the substrate 2 and the chamber upper cover 51. Thus, the problem that a flow rate of the process gas of the edge region of the upper surface of the substrate is different from a flow rate of the process gas of another region may be improved.

In some embodiments, the first block ring 3 and the second block ring 4 are coaxially arranged. In some embodiments, a positioning mechanism may be arranged between the first block ring 3 and the second block ring 4 to cause the first block ring 3 and the second block ring 4 to always remain coaxially arranged during installation.

In some embodiments, the reaction chamber further includes a heating element. The heating element may be configured to heat the base. The base may be heated by the heating element, which can cause the substrate 2 on the base to reach the reaction temperature. Thus, the substrate 2 may react with the process gas to complete the required process. The heating element may include a heating wire located in the base

In some embodiments, the reaction chamber may be a chemical vapor deposition chamber. As shown in FIG. 3, a top wall of the chamber body 5 is provided with a gas inlet channel. The sidewall of the chamber body 5 is provided with an exhaust gas channel.

In some embodiments, the chamber body 5 may include a sidewall 52 and a chamber upper cover 51 arranged at the top of the sidewall 52. The chamber upper cover 51 may be used as a top wall of the chamber body 5. The gas inlet channel that is configured to transfer the process gas into the reaction chamber may be a through-hole arranged in the chamber upper cover 51. The gas inlet channel may be arranged above the substrate 2. Thus, the process gas may be transferred to the upper surface of the substrate 2 after passing through the gas inlet channel. The exhaust gas channel may be a through-hole arranged on the sidewall 52. The height of the exhaust gas channel may be lower than the height of the second block ring 4.

An operation process of the reaction chamber provided by embodiments of the present disclosure is explained by taking the process of depositing the metal tungsten on the substrate 2 as an example.

In some embodiments, the process gas and the carrier gas may be transferred to the upper surface of the substrate 2 through the gas inlet channel in the chamber upper cover 51. The process gas may react on the upper surface of the substrate 2 to deposit metal tungsten on the upper surface of the substrate 2. The purge gas may be transferred to the edge of the upper surface of the substrate 2 by passing through the purge gas channel formed between the inner peripheral surface of the first block ring 3, the inner peripheral surface of the body member 41 of the second block ring 4, the upper surface of the edge member 12, the outer peripheral surface of the carrier member 11, the lower surface of the protrusion of the shield member 42, and the outer peripheral surface and the edge of the upper surface of the substrate 2, and may blow away the process gas at the edge. Therefore, the metal tungsten may not be deposited at the edge of the upper surface of the substrate 2, and a circle of edge exclusion region may be formed at the edge of the upper surface of the substrate 2. The carrier gas, the remaining process gas, and the by-product gas generated by the reaction may flow outwards via the exhaust gas channel between the second block ring 4 and the chamber upper cover 51, and eventually may be discharged from the reaction chamber via the exhaust gas channel on the sidewall 52.

The above embodiments are merely exemplary embodiments for illustrating the principles of the present disclosure, but the present disclosure is not limited there the embodiments. Various variations and improvements may be made by those of ordinary skill in the art without departing from the spirit and essence of the present disclosure. These variations and improvements are also regarded as the protection scope of the present disclosure.

What is claimed is:

1. A reaction chamber comprising:
a chamber body; and
a base arranged in the chamber body and including:
a carrier member configured to carry a substrate and an edge member arranged around the carrier member, a height of an upper surface of the carrier member being greater than a height of an upper surface of the edge member;
a first block ring arranged on the upper surface of the edge member and around the carrier member, the upper surface of the carrier member being higher than an upper surface of the first block ring;
a second block ring on the upper surface of the first block ring and including:
a body member; and
a shield member arranged on a side of the body member away from the first block ring, wherein:
the shield member protrudes from a surface of the second block ring opposite to the carrier member; and
the shield member is configured to shield an edge of the upper surface of the substrate.

2. The reaction chamber according to claim 1, wherein a lower surface of the shield member and the upper surface of the carrier member have a first predetermined vertical distance therebetween.

3. The reaction chamber according to claim 2, wherein:
an upper surface of the body member and the upper surface of the carrier member have a second predetermined vertical distance therebetween; and
the second predetermined vertical distance is less than or equal to the first predetermined vertical distance.

4. The reaction chamber according to claim 1, wherein:
the shield member includes an outer ring member, a flat member, and an inner ring member arranged in sequence along a direction close to the carrier member; and
along the direction close to the carrier member, a thickness of the inner ring member gradually decreases, and a thickness of the outer ring member gradually increases.

5. The reaction chamber according to claim 4, wherein a longitudinal cross-section of the shield member is trapezoidal in a radial direction of the shield member.

6. The reaction chamber according to claim 4, wherein the inner ring member, the outer ring member, and the flat member have a same dimension in a radial direction of the shield member.

7. The reaction chamber according to claim 1, wherein the first block ring and the second block ring are coaxially arranged.

8. The reaction chamber according to claim 1, wherein:
a thickness of the body member is between 2 mm and 8 mm; and
a thickness of the shield member is between 0.7 mm and 2.7 mm.

9. The reaction chamber according to claim 1, wherein the body member and the shield member are formed as an integrated structure.

10. The reaction chamber according to claim 1, wherein:
the reaction chamber is a chemical vapor deposition chamber;
a top wall of the chamber body is provided with a gas inlet channel; and
a sidewall of the chamber body is provided with an exhaust gas channel.

11. A semiconductor device comprising a reaction chamber including:
a chamber body; and
a base arranged in the chamber body and including:
a carrier member configured to carry a substrate and an edge member arranged around the carrier member, a height of an upper surface of the carrier member being greater than a height of an upper surface of the edge member;
a first block ring arranged on the upper surface of the edge member and around the carrier member, the upper surface of the carrier member being higher than an upper surface of the first block ring;
a second block ring on the upper surface of the first block ring and including:
a body member; and
a shield member arranged on a side of the body member away from the first block ring, wherein:
the shield member protrudes from a surface of the second block ring opposite to the carrier member; and
the shield member is configured to shield an edge of the upper surface of the substrate.

12. The semiconductor device according to claim 11, wherein a lower surface of the shield member and the upper surface of the carrier member have a first predetermined vertical distance therebetween.

13. The semiconductor device according to claim 12, wherein:
an upper surface of the body member and the upper surface of the carrier member have a second predetermined vertical distance therebetween; and
the second predetermined vertical distance is less than or equal to the first predetermined vertical distance.

14. The semiconductor device according to claim 11, wherein:
the shield member includes an outer ring member, a flat member, and an inner ring member arranged in sequence along a direction close to the carrier member; and
along the direction close to the carrier member, a thickness of the inner ring member gradually decreases, and a thickness of the outer ring member gradually increases.

15. The semiconductor device according to claim 14, wherein a longitudinal cross-section of the shield member is trapezoidal in a radial direction of the shield member.

16. The semiconductor device according to claim 14, wherein the inner ring member, the outer ring member, and the flat member have a same dimension in a radial direction of the shield member.

17. The semiconductor device according to claim 11, wherein the first block ring and the second block ring are coaxially arranged.

18. The semiconductor device according to claim 11, wherein:
a thickness of the body member is between 2 mm and 8 mm; and
a thickness of the shield member is between 0.7 mm and 2.7 mm.

19. The semiconductor device according to claim 11, wherein the body member and the shield member are formed as an integrated structure.

20. The semiconductor device according to claim 11, wherein:
the reaction chamber is a chemical vapor deposition chamber;
a top wall of the chamber body is provided with a gas inlet channel; and
a sidewall of the chamber body is provided with an exhaust gas channel.
